(19) United States
(12) Patent Application Publication
(10) Pub. No.: US 2018/0034009 A1
(43) Pub. Date: Feb. 1, 2018

(54) MASK AND METHOD FOR MAKING SAME

(71) Applicant: HON HAI PRECISION INDUSTRY CO., LTD., New Taipei (TW)

(72) Inventors: JEN-JIE CHEN, New Taipei (TW); CHANG-TING LIN, New Taipei (TW); PO-YI LU, New Taipei (TW)

(21) Appl. No.: 15/641,278

(22) Filed: Jul. 4, 2017

Related U.S. Application Data
(60) Provisional application No. 62/368,185, filed on Jul. 29, 2016.

(51) Int. Cl. H01L 51/56; H01L 51/00

(52) U.S. Cl. CPC H01L 51/56; H01L 51/0011; H01L 51/0012

(57) ABSTRACT

A mask includes a plastic layer, a frame, and a plurality of magnetic elements. The plastic layer has a first surface and a second surface, the first surface and the second surface are on two opposite sides of the plastic layer facing away from each other. The plastic layer has a plurality of openings extending through the first surface and the second surface. The frame is on the first surface and covers a periphery of the plastic layer. The magnetic elements protrude from the first surface. Each magnetic element tapers along a direction away from the first surface.

### FIELD

The subject matter herein generally relates to a mask and a method for making the mask, and particularly relates to a mask for depositing an organic light emitting material layer on a substrate.

### BACKGROUND

The method for making an organic light emitting diode (OLED) display panel generally includes a step of forming an organic light-emitting material layer on a substrate (e.g., a thin film transistor substrate) by vapor deposition. A mask is used in the step of forming the organic light-emitting material layer on the substrate and the mask is positioned on the substrate. The mask defines a plurality of through holes, thus evaporated material from an evaporation source can pass through the through holes and be deposited on the substrate. The organic light-emitting material deposited on the substrate by each through hole corresponds to a sub-pixel of the OLED display panel. Typically, the size of each through-hole is designed to be equal to the size of a sub-pixel. However, a size of the sub-pixel formed by using the mask is often greater than a size of the desired sub-pixels because of gaps between the mask and the substrate during the deposition process. This phenomenon is called shadow effect.

### BRIEF DESCRIPTION OF THE DRAWINGS

Implementations of the present technology will now be described, by way of example only, with reference to the attached figures.

FIG. 1 is a planar view of an exemplary embodiment of a mask for depositing an organic light-emitting layer.

FIG. 2 is a cross-sectional view of the mask along line II-II of FIG. 1.

FIG. 3 is an isometric view showing two modified examples of the magnetic elements of the mask of FIG. 1.

FIG. 4a through FIG. 4g are cross-sectional views showing manufacturing processes of a first exemplary embodiment of a method for making the mask of FIG. 1.

FIG. 5a through FIG. 5f are cross-sectional views showing manufacturing processes of a second exemplary embodiment of a method for making a mask.

FIG. 6 is a cross-sectional view showing the mask of FIG. 1 in use.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the exemplary embodiments described herein. However, it will be understood by those of ordinary skill in the art that the exemplary embodiments described herein may be practiced without these specific details. In other instances, methods, procedures, and components have not been described in detail so as not to obscure the related relevant feature being described. Also, the description is not to be considered as limiting the scope of the exemplary embodiments described herein. The drawings are not necessarily to scale and the proportions of certain parts may be exaggerated to better illustrate details and features of the present disclosure.

The term “coupled” is defined as connected, whether directly or indirectly through intervening components, and is not necessarily limited to physical connections. The connection can be such that the objects are permanently connected or releasably connected. The term “comprising” when utilized, means “including, but not necessarily limited to”; it specifically indicates open-ended inclusion or membership in the so-described combination, group, series, and the like.

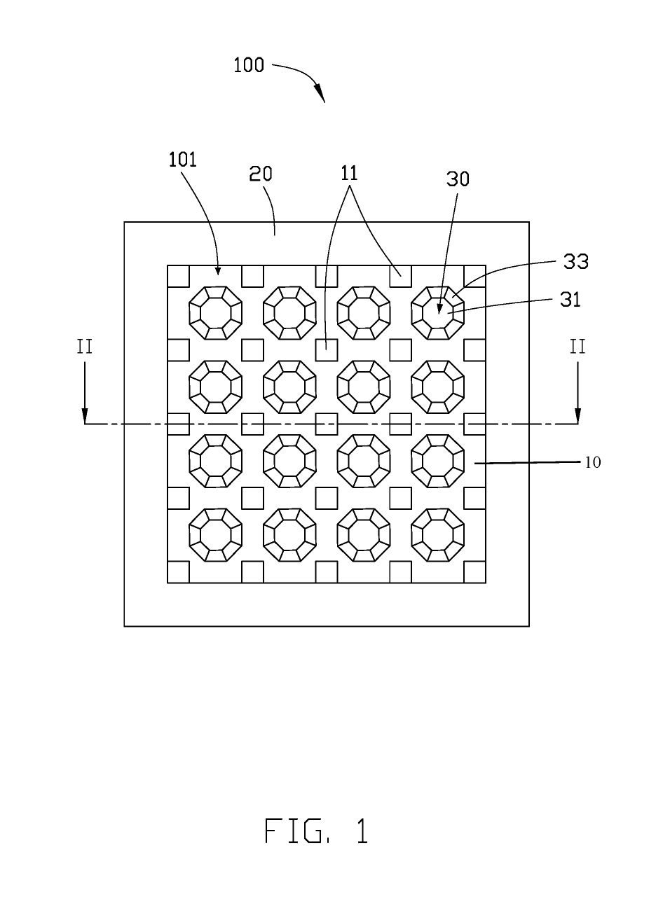

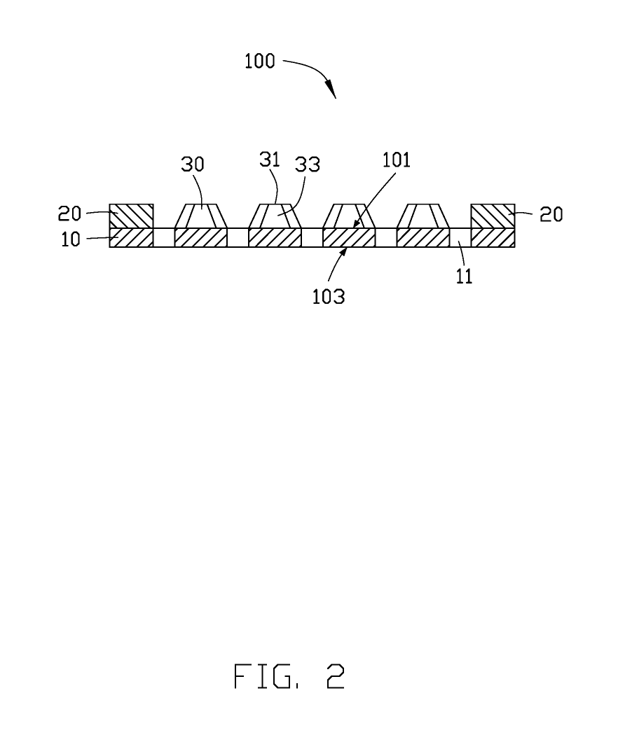

FIG. 1 and FIG. 2 illustrate a mask 100 according to an exemplary embodiment. The mask 100 includes a plastic layer 10 and a frame 20 coupled to the plastic layer 10. As shown in FIG. 2, the plastic layer 10 includes a first surface 101 and a second surface 103. The first surface 101 and the second surface 103 are on opposite sides of the plastic layer 10 facing away from each other. The frame 20 is on the first surface 101 and covers a periphery of the plastic layer 10. The frame 20 extends along the periphery of the first surface 101 and forms a closed rectangular. The plastic layer 10 defines a plurality of openings 11 spaced apart from each other. Each opening 11 extends through the plastic layer 10 from the first surface 101 to the second surface 103. In the present exemplary embodiment, the plurality of openings 11 are arranged in an array.

The plastic layer 10 is made of a common plastic material, such as, but not limited to, polyimide. The frame 20 is configured to support the plastic layer 10 and improve a strength of the mask 100. The frame 20 may be made of a metal or an alloy. In some exemplary embodiments, the frame 20 can be made of a magnetic metal or an magnetic alloy.

When depositing an organic light-emitting material layer of the OLED display panel on a substrate, a mask and the substrate (e.g., a thin film transistor substrate) are placed in a deposition apparatus (e.g., a vapor deposition machine, not shown) having a magnetic plate (not shown); and the magnetic plate, the substrate, and the mask are stacked in that order. The mask is required to be magnetized. Without magnetization, a gap would form between the mask and the substrate. The mask being magnetized causes attraction between the mask and the magnetic plate to bring and keep the mask and the substrate close together, which reduces or avoids shadow effect.

When the frame 20 is made of a magnetic metal or alloy, the mask 100 is magnetic. However, the frame 20 only covers a periphery of the plastic layer 10, thus other portions of the plastic layer 10 may not be closely attached to the substrate. To solve this problem, the frame 20 further includes a plurality of magnetic elements 30 protruding from the first surface 101 of the plastic layer 10. The magnetic elements 30 are spaced apart from each other. The frame 20 surrounds the plurality of magnetic elements 30. The magnetic elements 30 do not cover any opening 11. In the present exemplary embodiment, each magnetic element 30 is located between four adjacent openings 11.

Each magnetic element 30 may be made of ink containing magnetic particles. The magnetic particles may be iron particles, nickel particles, or cobalt particles as conventionally used in the art. Alternatively, each magnetic element 30 may be made of a magnetic metal or an magnetic alloy, such as iron, cobalt, nickel, or invar alloy. When the magnetic element 30 is made of a magnetic metal or an magnetic alloy, it is preferable that the frame 20 and the magnetic elements 30 are made of a same material.

As shown in FIG. 1 and FIG. 2, each magnetic element 30 includes a bottom surface 31 opposite to the first surface 101 and at least one side surface 33 connected between the bottom surface 31 and the first surface 101. Each magnetic element 30 has a substantially frustum-like shape, and each magnetic element 30 tapers from the first surface 101 towards the bottom surface 31. A size of a cross section of each magnetic element 30 parallel to the first surface 101 gradually becomes smaller along a direction from the first surface 101 towards the bottom surface 31. Thus, the at least one side surface 33 of each magnetic element 30 is inclined with respect to the first surface 101 of the plastic layer 10 (e.g., the internal angle between the side surface 33 and the first surface 101 is 25-70 degrees).

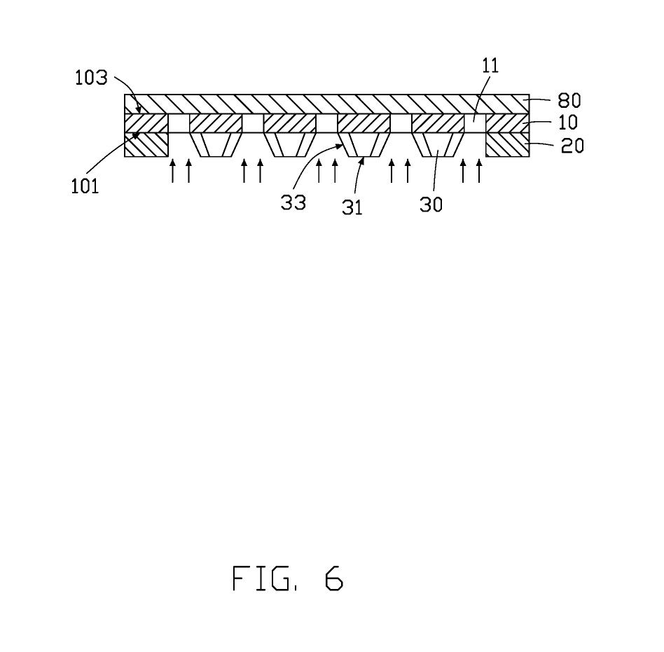

As shown in FIG. 6, when a substrate 80 is deposited to form an organic light-emitting layer, the mask 100 is stacked on the substrate 80, and the substrate 80 is located at a side of the mask 100 having the second surface 103. Evaporated material from a side of the mask 100 having the first surface 101 passes through the openings 11 and is deposited on the substrate 80. The side surface 33 of each magnetic element 30 is inclined to the first surface 101 of the plastic layer 10, which facilitates the introduction of the evaporated material into the openings 11 along the side surface 33. Thus, the evaporated material can be deposited on a predetermined position of the substrate 80 with a precise demarcation, which further reduces or avoids shadow effect. It is to be understood that the inclination angle of the side surface 33 to the first surface 101, and the height and shape of the magnetic element 30, can be adjusted so that the evaporated material can be deposited to a predetermined position of the substrate 80.

In the present exemplary embodiment, as shown in FIG. 1 and FIG. 2, each magnetic element 30 includes the bottom surface 31 having a regular octagon shape and eight side surfaces 33 connected between the bottom surface 31 and the first surface 101. Each side face 33 is inclined to the first surface 101 of the plastic layer 10.

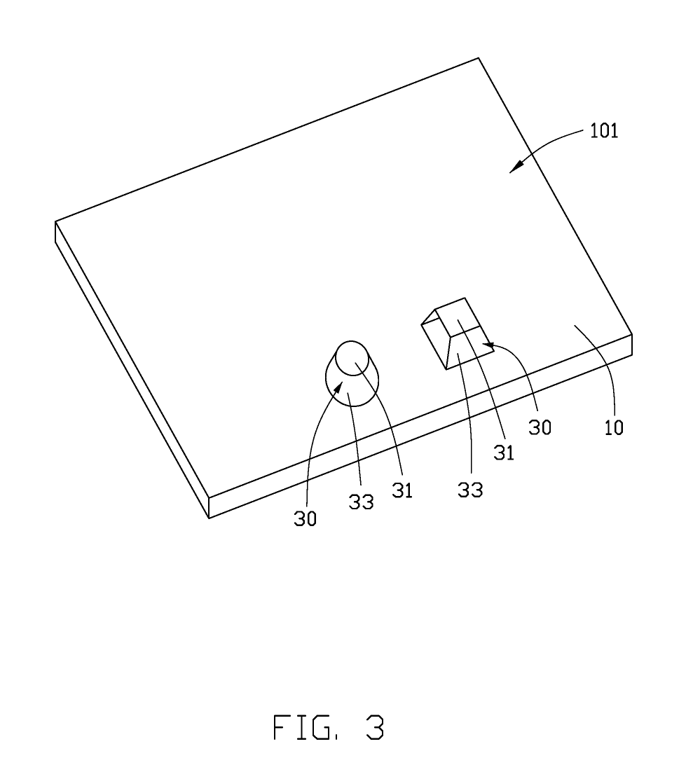

The shape of the magnetic element 30 may be adjusted as desired. As shown in FIG. 3, one magnetic element 30 includes a bottom surface 31 having a rectangle shape and four side surfaces 33 connected between the bottom surface 31 and the first surface 101. Another magnetic element 30 can include a bottom surface 31 having a circular shape and a curved side surface 33 connected between the bottom surface 31 and the first surface 101. For simplicity, FIG. 3 only shows magnetic elements 30 which have different shapes on the plastic layer 10; and FIG. 3 simply shows the plastic layer 10 and the magnetic elements 30, other elements and features are not shown.

It is to be understood that the shapes of the magnetic element 30 are not limited to those shown in the figures, but may be various other regular or irregular shapes.

As in FIG. 1, the magnetic elements 30 are arranged uniformly. It is to be understood that an arrangement of the magnetic elements 30 may be adjusted as appropriate, and is not limited to the uniform arrangement shown in FIG. 1. For example, the magnetic elements 30 may be arranged densely in a region of the plastic layer 10 attracting the magnetic plate (not shown), for reinforcement. The magnetic elements 30 may be arranged sparsely in other regions of the plastic layer 10.

A method for making the mask 100 according to a first exemplary embodiment includes the following steps. The magnetic element 30 of the mask 100 is made of an ink containing magnetic particles.

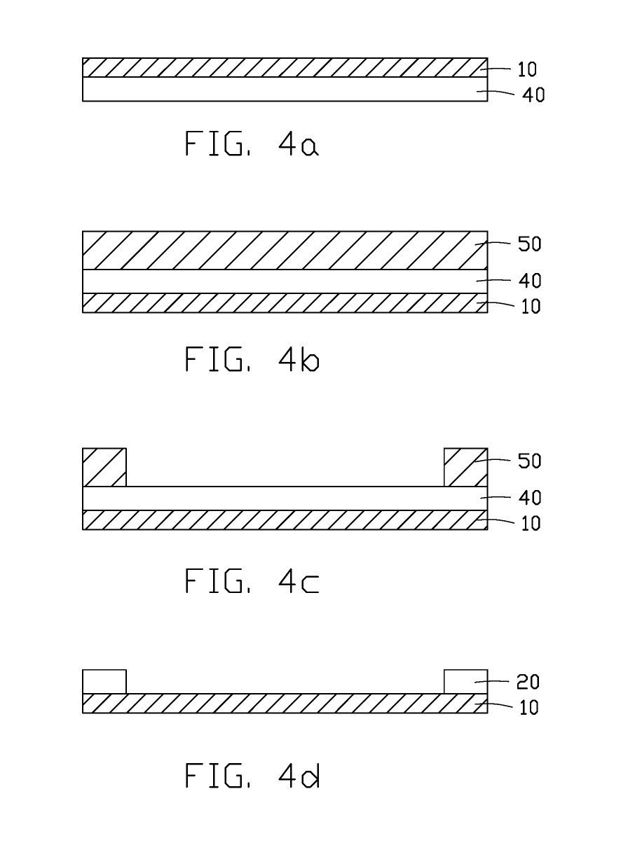

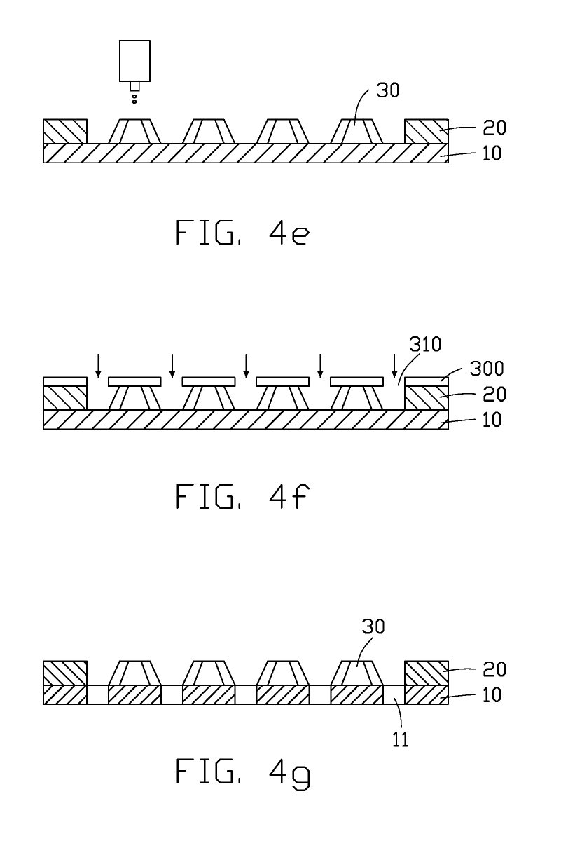

Step S1: As shown in FIG. 4a, a metal plate 40 is provided and a plastic layer 10 is formed on a surface of the metal plate 40.

The plastic layer 10 may be formed on the metal plate 40 by injection molding. The metal plate 40 may be made of a metal or an alloy. The plastic layer 10 may be made of polyimide.

Step S2: as shown in FIG. 4b through FIG. 4d, the metal plate 40 is partially etched to remove a central portion of the metal plate 40, and remaining portion of the metal plate 40 is formed as a frame 20 that covers only a periphery of the plastic layer 10.

The step S2 may include the following steps: forming a photoresist layer 50 on a surface of the metal plate 40 away from the plastic layer 10 as shown in FIG. 4b; exposing and developing the photoresist layer 50 to make the photoresist layer 50 partially cover the metal plate 40 as shown in FIG. 4c; etching and removing the portion of the metal plate 40 that is not covered by the photoresist layer 50, and the remaining metal plate 40 forms a frame 20 that covers a periphery of the plastic layer 10 as shown in FIG. 4d. The remaining photoresist layer 50 is finally removed.

Step S3: as shown in FIG. 4e, a plurality of magnetic elements 30 spaced apart from each other are formed on the surface of the plastic layer 10 having the frame 20.

The plurality of magnetic elements 30 are surrounded by the frame 20. Each magnetic element 30 is made of ink containing magnetic particles. The plurality of magnetic elements 30 are formed on the plastic layer 10 by an ink-jet printing process. The shape and the size of the magnetic element 30 can be controlled by adjusting parameters of the ink-jet printing process (e.g., ink ejection amount, ink ejection speed, viscosity of the ink, etc.), thus the magnetic element 30 tapers along a direction away from the plastic layer 10. For example, the height and area of the magnetic element 30 can be controlled by controlling ink ejection amount when forming a magnetic element 30.

Step S4: as shown in FIG. 4f through FIG. 4g, a plurality of openings 11 are formed in the plastic layer 10.

Each opening 11 extends through the plastic layer 10. The step S4 may include the following: providing a shielding film 300 defining a plurality of through holes 310; positioning the shielding film 300 at a side of the plastic layer 10 having the frame 20 as shown in FIG. 4f; laser-etching a portion of the plastic layer 10 not covered by the frame 20 and the magnetic elements 30 to form a plurality of openings 11 as shown in FIG. 4g, each through hole 310 corresponding to one opening 11.

A method for making the mask 200 according to a second exemplary embodiment includes the following steps. The magnetic elements 30 and the frame 20 of the mask 100 are made of a same material.

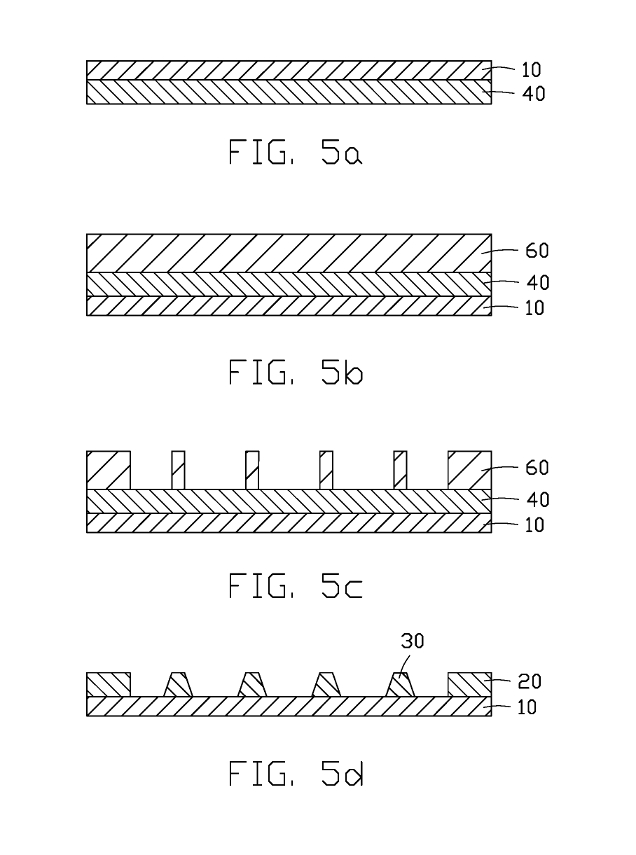

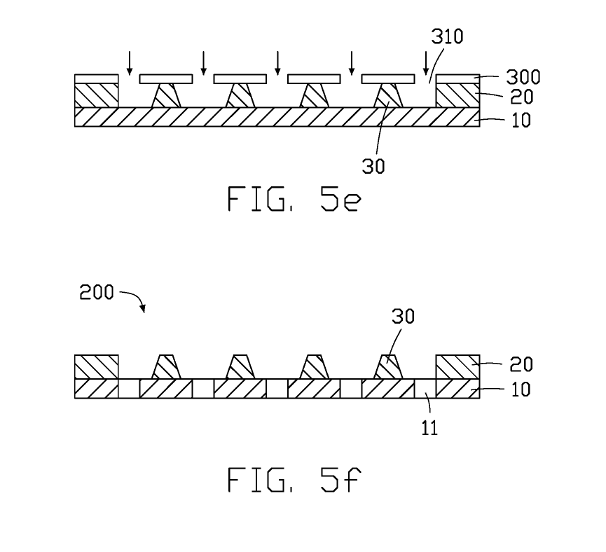

Step S1: as shown in FIG. 5a, a metal plate 40 is provided and a plastic layer 10 is formed on a surface of the metal plate 40.

The plastic layer 10 may be formed on the metal plate 40 by injection molding. The metal plate 40 may be made of a magnetic metal or an magnetic alloy, such as invar alloy. The plastic layer 10 may be made of polyimide.

Step S2: as shown in FIG. 5b through FIG. 5d, the metal plate 40 is etched to remove a portion of the metal plate 40, and remaining portion of the metal plate 40 forms a frame 20 and a plurality of magnetic elements 30 spaced apart from each other. The frame 20 covers only a periphery of the plastic layer 10. The plurality of magnetic elements 30 is surrounded by the frame 20.

The step S2 may include the following: forming a photoresist layer 60 on the surface of the metal plate 40 away from the plastic layer 10 as shown in FIG. 5b; exposing and developing the photoresist layer 60 to make the photoresist layer 60 partially cover the metal plate 40, as shown in FIG. 5c; wet-etching the portion of the metal plate 40 not covered by the photoresist layer 60. The remaining metal plate 40 forms a frame 20 and a plurality of magnetic elements 30 spaced apart from each other, as shown in FIG. 5d, and the remaining photoresist layer 60 is finally removed. The shape of the magnetic element 30 can be adjusted by controlling parameters of the wet etching process so that the magnetic element 30 tapers along a direction away from the plastic layer 10.

Step S3: as shown in FIG. 5e through FIG. 5f, a plurality of openings 11 is defined in the plastic layer 10.

Each opening 11 extends through the plastic layer 10. The step S3 may include the following: providing a shielding film 300 defining a plurality of through holes 310; positioning the shielding film 300 at a side of the plastic layer 10 having the frame 20 as shown in FIG. 5e; laser-etching the plastic layer 10 not covered by the frame 20 and the magnetic elements 30 to form a plurality of openings 11 as shown in FIG. 5f, each through hole 310 corresponding to one opening 11.

It is to be understood, even though information and advantages of the present exemplary embodiments have been set forth in the foregoing description, together with details of the structures and functions of the present exemplary embodiments, the disclosure is illustrative only. Changes may be made in detail, especially in matters of shape, size, and arrangement of parts within the principles of the present exemplary embodiments to the full extent indicated by the plain meaning of the terms in which the appended claims are expressed.

What is claimed is:

1. A mask comprising:
a plastic layer, the plastic layer comprising a first surface and a second surface, the first surface and the second surface on opposite sides of the plastic layer facing away from each other, the plastic layer defining a plurality of openings, each of the plurality of openings extending through the first surface and the second surface;
a frame on the first surface, the frame covering a periphery of the plastic layer; and
a plurality of magnetic elements protruding from the first surface;
wherein each of the plurality of magnetic elements tapers along a direction away from the first surface.

2. The mask of claim 1, wherein each of the plurality of magnetic elements is made of ink containing magnetic particles.

3. The mask of claim 1, wherein each of the plurality of magnetic elements is made of a magnetic metal or an magnetic alloy.

4. The mask of claim 1, wherein the frame is made of a metal or an alloy.

5. The mask of claim 4, wherein the frame is made of a magnetic metal or an magnetic alloy.

6. The mask of claim 5, wherein the frame and the plurality of magnetic elements are made of a same material.

7. The mask of claim 1, wherein each of the plurality of magnetic elements comprises a bottom surface opposite to the first surface and at least one side surface connected between the bottom surface and the first surface; the at least one side surface is inclined to the first surface.

8. The mask of claim 1, wherein the plurality of openings are arranged in an array.

9. The mask of claim 8, wherein each of the plurality of magnetic elements located between four adjacent openings.

10. The mask of claim 8, wherein the plurality of magnetic elements are surrounded by the frame.

11. A method for making a mask comprising:
forming a plastic layer on a metal plate;
partially etching the metal plate to form a frame on the plastic layer, the frame covering a periphery of the plastic layer;
forming a plurality of magnetic elements on a surface of the plastic layer having the frame, wherein each of the plurality of magnetic elements tapers along a direction away from the plastic layer;
forming a plurality of openings through the plastic layer, each of plurality of openings not overlapping with the frame and any of the plurality of magnetic elements.

12. The method for making a mask of claim 11, wherein each of the plurality of magnetic elements is made of ink containing magnetic particles.

13. The method for making a mask of claim 12, wherein the plurality of magnetic elements are formed on the plastic layer by an ink-jet printing process.

14. The method for making a mask of claim 11, wherein the plurality of openings is arranged in an array of rows and columns; each of the plurality of magnetic elements is located between four adjacent openings.

15. The mask of claim 11, wherein the plurality of magnetic elements are surrounded by the frame.

16. A method for making a mask comprising:
forming a plastic layer on a metal plate, the metal plate being made of a magnetic metal or magnetic alloy;
partially etching the metal plate to form a frame and a plurality of magnetic elements spaced apart from each other on the plastic layer, the frame covering a periphery of the plastic layer, and the plurality of magnetic elements surrounded by the frame;
forming a plurality of openings through the plastic layer, each of plurality of openings not overlapping with the frame and any of the plurality of magnetic elements.

17. The method for making a mask of claim 16, wherein the plurality of openings is arranged in an array of rows and columns; each of the plurality of magnetic elements located between four adjacent openings.
